(19) United States
(12) Patent Application Publication
(10) Pub. No.: US 2016/0197097 A1
(43) Pub. Date: Jul. 7, 2016

(54) DISPLAY DEVICE

(71) Applicant: Samsung Display Co., Ltd., Yongin-City (KR)

(72) Inventor: Sung Hyuk Kim, Asan-si (KR)

(21) Appl. No.: 14/792,460

(22) Filed: Jul. 6, 2015

(30) Foreign Application Priority Data
Jan. 2, 2015 (KR) 10-2015-0000224

(51) Int. Cl. H01L 27/12; H01L 51/52; H01L 27/32

(52) U.S. Cl. CPC H01L 27/124; H01L 27/3276; H01L 51/524; H01L 27/1248

(57) ABSTRACT

A display device is disclosed. In one aspect, the device includes a Substrate and a pad portion positioned over the substrate. The display device also includes an integrated circuit chip electrically connected to the pad portion and formed over the substrate. The pad portion includes a first pad positioned over the substrate, a second pad positioned over the first pad, and a third pad positioned over the second pad.

### INCORPORATION BY REFERENCE TO ANY PRIORITY APPLICATIONS

This application claims priority to and the benefit of Korean Patent Application No. 10-2015-0000224 filed in the Korean Intellectual Property Office on Jan. 2, 2015, the entire contents of which are incorporated herein by reference.

### BACKGROUND

1. Field

The described technology generally relates to a display device.

2. Description of the Related Technology

Generally, a display device such as an organic light emitting diode (OLED) display is manufactured by forming an element on a substrate such as glass or plastic, and integrated circuit chips generating various signals for driving the display device are mounted on a predetermined region of the substrate included in the display device. Here, the integrated circuit chips may be divided into a chip on glass (COG), a chip on flexible printed circuit board (COF), or the like according to a mounted portion of the integrated circuit chip.

Among the integrated circuit chips, in the case of the COG in which the integrated circuit chip is mounted on the substrate, the integrated circuit chip is mounted on the substrate with an anisotropic conductive film (ACF) serving as an interposer interposed between an electrode pad formed on the substrate and a terminal of the integrated circuit chip.

### SUMMARY OF CERTAIN INVENTIVE ASPECTS

One inventive aspect relates to a display device in which an integrated circuit chip is mounted on a substrate.

Another aspect is a display device having advantages of preventing conductive balls included in an anisotropic conductive film from pressing a passivation layer when an integrated circuit chip and an electrode pad are connected to each other.

Another aspect is a display device including: a substrate; a pad part positioned on the substrate; and an integrated circuit chip electrically connected with the pad part to be mounted on the substrate, in which the pad part includes a first pad positioned on the substrate, a second pad positioned on the first pad, and a third pad positioned on the second pad.

The first pad may be formed of the same material as a first gate electrode forming a thin film transistor, the second pad may be formed of the same material as a second gate electrode forming the thin film transistor, and the third pad may be formed of the same material as a source electrode and a drain electrode forming the thin film transistor.

A second gate insulating layer may be positioned between the first pad and the second pad, and the second gate insulating layer may include a first region in which a first contact hole is not formed and a second region in which the first contact hole is formed.

The first pad and the second pad may be electrically connected to each other through the first contact hole in the second region.

A passivation layer may be positioned between the second pad and the third pad, and the passivation layer may include a second contact hole connecting the second pad and the third pad.

The integrated circuit chip may include a main body part and a bump positioned below the main body part.

The bump may be attached to the third pad.

Before the bump of the integrated circuit chip is attached, an anisotropic conductive film containing conductive balls may be coated on the third pad.

The bump of the integrated circuit chip may be electrically connected to the third pad through the anisotropic conductive film.

The second pad may be formed at a predetermined height.

The height of the second pad may be 2,000 Å or more.

The display device may further include: a first electrode electrically connected with the drain electrode; an organic emission layer positioned on the first electrode; and a second electrode positioned on the organic emission layer.

The display device may further include an encapsulation body coupled with the substrate, in which the pad part may be formed at a portion of the substrate which is not covered by the encapsulation body.

The technical objects desired to be achieved in the present invention are not limited to the aforementioned objects, and other technical objects not described in the above will be apparent to those skilled in the art from the disclosure of the present invention.

Another aspect is a display device, comprising: a substrate; a pad portion positioned over the substrate; and an integrated circuit chip electrically connected to the pad portion and formed over the substrate, wherein the pad portion includes a first pad positioned over the substrate, a second pad positioned over the first pad, and a third pad positioned over the second pad.

The above display device further comprises a thin film transistor, wherein the thin film transistor includes first and second gate electrodes, and source and drain electrodes, wherein the first pad is formed of the same material as the first gate electrode, wherein the second pad is formed of the same material as the second gate electrode, and wherein the third pad is formed of the same material as the source and drain electrodes. The above display device further comprises a second gate insulating layer positioned between the first and second pads, and wherein the second gate insulating layer includes a first region in which a first contact hole is not formed and a second region in which the first contact hole is formed. In the above display device, the first and second pads are electrically connected to each other through the first contact hole in the second region.

The above display device further comprises a passivation layer positioned between the second and third pads, wherein the passivation layer includes a second contact hole connecting the second and third pads. In the above display device, the second and third pads are electrically connected to each other through the second contact hole. In the above display device, the integrated circuit chip includes a main body and a bump positioned below the main body. In the above display device, the bump is attached to the third pad. The above display device further comprises an anisotropic conductive film containing a plurality of conductive balls coated on the third pad.

In the above display device, the bump of the integrated circuit chip is electrically connected to the third pad through the anisotropic conductive film. In the above display device, the second pad has a height of about 2,000 Å or greater. The above display device further comprising: a first electrode electrically connected to a drain electrode; an organic emission layer positioned over the first electrode; and a second electrode positioned over the organic emission layer. The above display device further comprises an encapsulation body connected to the substrate, wherein the pad portion is formed at a region of the substrate which is not covered by the encapsulation body.

Another aspect is a display device, comprising: a substrate; at least three pads positioned over the substrate; and an integrated circuit chip electrically connected to the pads and formed over the substrate, wherein the at least three pads comprise a first pad positioned over the substrate, a second pad positioned over the first pad, and a third pad positioned over the second pad.

In the above display device, the integrated circuit chip includes a main body and a bump positioned below the main body. In the above display device, the bump is formed substantially directly above the pads. The above display device further comprises an anisotropic conductive film containing a plurality of conductive balls coated on the third pad. In the above display device, at least some of the conductive balls are positioned between the third pad and the bump. In the above display device, each of the first and second pads has a substantially linear shape, and wherein the third pad has a non-linear shape. In the above display device, the second pad has a height of about 2,000 Å or greater.

According to at least one of the disclosed embodiments, when the integrated circuit chip is connected to the pad part on the substrate, the second pad is further included between the first pad and the third pad to form a higher step of the pad part than that of the thin film wire, and as a result, even in the case where the bump and the pad part are misaligned, a problem that the conductive balls are bumped into the passivation layer to form a crack may be prevented.

### BRIEF DESCRIPTION OF THE DRAWINGS

FIG. 1 is a perspective view illustrating a display device according to an exemplary embodiment.

FIG. 2 is a cross-sectional view illustrating the display device according to the exemplary embodiment.

FIG. 3 is a layout view illustrating a pixel structure of the display device according to the exemplary embodiment.

FIG. 4 is a cross-sectional view illustrating one pixel structure of the display device according to the exemplary embodiment.

FIG. 5 is a plan view enlarging part V of FIG. 1.

FIG. 6 is a cross-sectional view according to the exemplary embodiment.

FIG. 7 is a cross-sectional view according to the exemplary embodiment.

FIG. 8 is a cross-sectional view illustrating a display device according to a Comparative Example.

FIG. 9 is a cross-sectional view illustrating the display device according to the exemplary embodiment.

### DETAILED DESCRIPTION OF CERTAIN INVENTIVE EMBODIMENTS

In order to electrically connect the integrated circuit chip and the electrode pad through an anisotropic conductive film (ACF), the integrated circuit chip and the electrode pad are connected to each other by pressure and heat. In this case, when the integrated circuit chip and the electrode pad are misaligned, a problem can arise in that a crack occurs in a passivation layer while conductive balls included in the ACF between the integrated circuit chip and the electrode pad press the passivation layer.

Embodiments will be described more fully hereinafter with reference to the accompanying drawings, in which exemplary embodiments are shown. As those skilled in the art would realize, the described embodiments may be modified in various different ways, all without departing from the spirit or scope of the present invention.

Accordingly, the drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present invention is not limited thereto.

In the drawings, the thickness of layers, films, panels, regions, etc., are exaggerated for clarity. In the drawings, for understanding and ease of description, the thickness of some layers and areas is exaggerated. It will be understood that when an element such as a layer, film, region, or substrate is referred to as being “on” another element, it can be directly on the other element or intervening elements may also be present.

Further, hereinafter, as a display device, an organic light emitting device including an organic emission layer will be described as an exemplary embodiment, but the present invention is not limited thereto, and can apply to other types of displays such as a liquid crystal display, a plasma display panel, and a field emission display.

Further, in the accompanying drawing, an active matrix (AM) type organic light emitting device having a 2Tr-1Cap structure including two thin film transistors (TFTs) and one capacitor in one pixel is illustrated, but the present invention is not limited thereto. Accordingly, in the organic light emitting device, the number of TFTs, the number of capacitors, and the number of wires are not limited. Meanwhile, a pixel means a minimum unit displaying an image, and an organic light emitting panel displays the image through the plurality of pixels.

In this disclosure, the term “substantially” includes the meanings of completely, almost completely or to any significant degree under some applications and in accordance with those skilled in the art. The term “connected” includes an electrical connection.

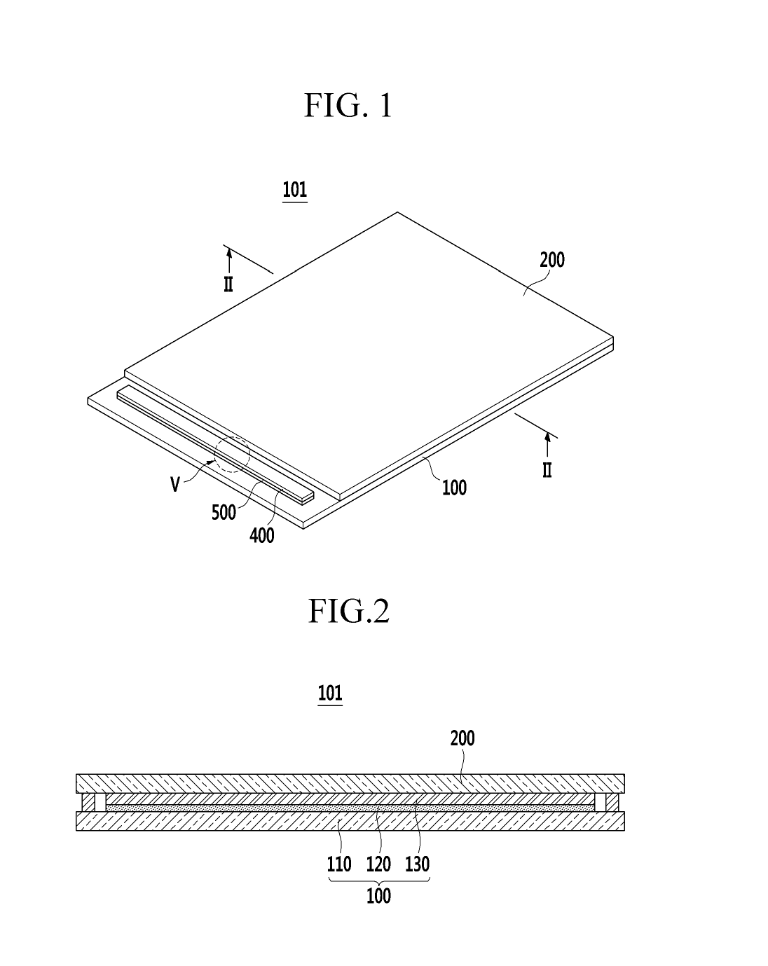

Hereinafter, a display device according to an exemplary embodiment will be described with reference to FIGS. 1 to 9.

FIG. 1 is a perspective view illustrating a display device 101 according to an exemplary embodiment.

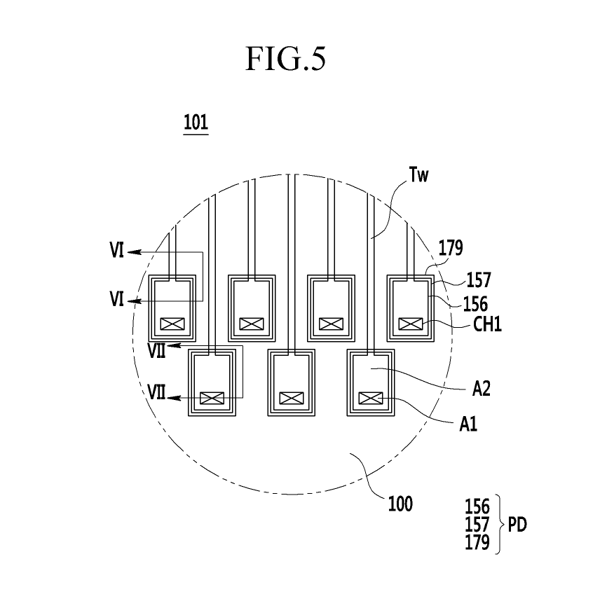

As illustrated in FIG. 1, the display device 101 includes a display panel 100, an encapsulation body 200, a pad portion PD (illustrated in FIGS. 5-9), an integrated circuit chip 400, and an anisotropic conductive film (ACF) 500.

The encapsulation body 200 has a size smaller than that of the display panel 100 and covers the display panel 100. As a result, a portion which is not covered by the encapsulation body 200 is formed on the display panel 100, and at the portion, the integrated circuit chip 400 is formed to be adjacent to the encapsulation body 200 to be mounted on the display panel 100 by the ACF 500.

FIG. 2 is a cross-sectional view illustrating the display device according to the exemplary embodiment, and a cross-sectional view taken along line II-II of FIG. 1.

As illustrated in FIG. 2, the display panel 100 includes a substrate 110, a wire part or wire portion 120, and an organic light emitting diode (OLED) 130.

The substrate 110 can be formed of an insulating member made of glass, quartz, ceramic, or plastic. However, the substrate 110 may be formed of a metallic member made of stainless steel.

The wire part 120 and the OLED 130 which are formed on the substrate 110 are positioned between the substrate 110 and the encapsulation body 200.

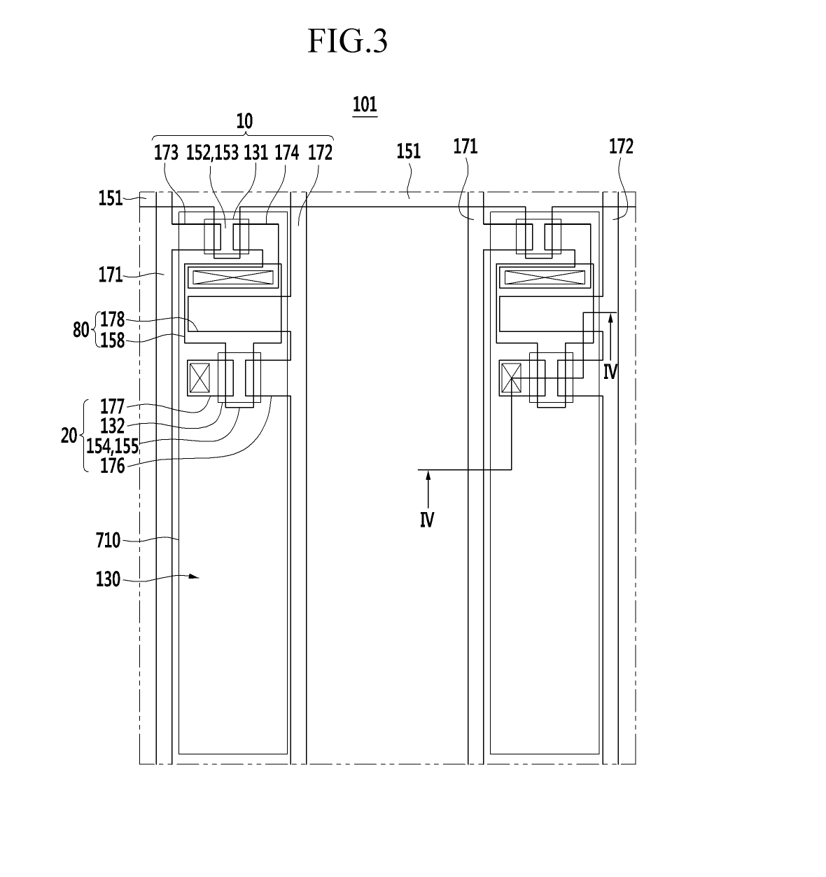

The wire part 120 includes first and second thin film transistors 10 and 20 (illustrated in FIG. 3) and drives the OLED 130. The OLED 130 emits light according to a driving signal received from the wire part 120.

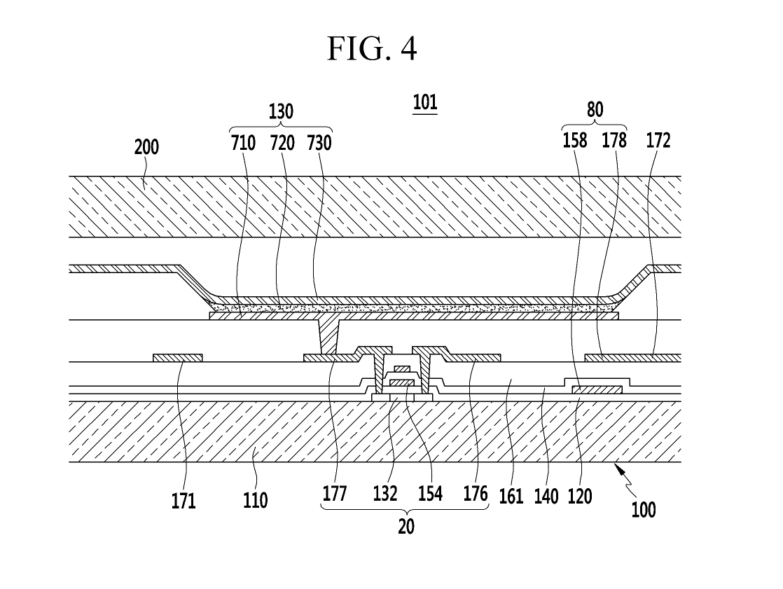

Detailed structures of the OLED 130 and the wire part 120 are illustrated in FIGS. 3 and 4, but the present invention is not limited to the structures illustrated in FIGS. 3 and 4. The OLED 130 and the wire part 120 may be formed in various structures within a range in which those skilled in the art may be easily modified and implemented.

Hereinafter, an internal structure of the display device 101 according to the exemplary embodiment will be described in detail with reference to FIGS. 3 and 4.

FIG. 3 is a layout view illustrating a pixel structure of the display device according to the exemplary embodiment. FIG. 4 is a cross-sectional view illustrating one pixel structure of the display device according to the exemplary embodiment and a cross-sectional view taken along line IV-IV of FIG. 3.

As illustrated in FIGS. 3 and 4, the display device 101 according to the exemplary embodiment includes a switching thin film transistor 10, a driving thin film transistor 20, a capacitor 80, and an OLED (OLED) 130, which are formed on the substrate 110 for every pixel, respectively. Here, the configuration including the switching thin film transistor 10, the driving thin film transistor 20, and the capacitor 80 is referred to as the wire part 120. In addition, the wire part 120 further includes a gate line 151 which is formed in one direction of the substrate 110, a data line 171 which insulatively crosses the gate line 151, and a common power line 172. Further, one pixel may be defined by a boundary made by the gate line 151, the data line 171, and the common power line 172, but the definition of the pixel is not necessarily limited thereto.

The OLED 130 includes a first electrode 710, an organic emission layer 720 formed on the first electrode 710, and a second electrode 730 formed on the organic emission layer 720. Here, the first electrode 710 is a positive (+) electrode which is a hole injection electrode, and the second electrode 730 is a negative (−) electrode which is an electron injection electrode. However, the present invention is not necessarily limited thereto, and according to a driving method of the display device 101, the first electrode 710 may become the negative electrode and the second electrode 730 may become the positive electrode. A hole and an electron are injected into the organic emission layer 720 from the first electrode 710 and the second electrode 730, respectively, and when an exiton in which the hole and the electron which are injected into the organic emission layer 720 are coupled with each other falls down from an excited state to a ground state, the organic emission layer 720 emits the light.

The organic emission layer 720 may also be configured by a single layer made of a light emitting material, and in order to enhance light emission efficiency, a multiple layer of a hole injection layer, a hole transport layer, an emitting material layer, an electron transport layer, and an electron injection layer may also be configured.

Further, in the display device 101, the OLED 130 emits light toward the encapsulation body 200. That is, the OLED 130 is configured by a top emission type. As a result, the first electrode 710 may be a reflective conductive material and the second electrode 730 may be made of a transmissive conductive material. However, the present invention is not limited to the structure, and may be configured by a bottom emission type in which the first electrode 710 is made of a transmissive conductive material and the second electrode 730 is made of a reflective conductive material, or may also be configured by a both-side emission type in which both the first electrode 710 and the second electrode 730 are made of the transmissive conductive material.

The capacitor 80 includes a pair of capacitor plates 158 and 178 formed with an interlayer insulating layer 161 therebetween. Here, the interlayer insulating layer 161 can function as a dielectric material for the capacitor 80, and a capacitance of the capacitor 80 is determined by a charge charged in the capacitor 80 and a voltage between the capacitor plates 158 and 178.

The switching thin film transistor 10 includes a switching semiconductor layer 131, a first switching gate electrode 152, a second switching gate electrode 153, a switching source electrode 173, and a switching drain electrode 174. The driving thin film transistor 20 includes a driving semiconductor layer 132, a first driving gate electrode 154, a second driving gate electrode 155, a driving source electrode 176, and a driving drain electrode 177.

On the substrate 110, the semiconductor layers 131 and 132, the first gate insulating layer 120, the first gate electrodes 152 and 154, the second gate insulating layer 140, the second gate electrodes 153 and 155, and the passivation layer 161 are sequentially formed.

The switching thin film transistor 10 is used as a switching element which selects a pixel to emit light. The first switching gate electrode 152 is connected to the gate line 151. Although not illustrated, the first switching gate electrode 152 and the second switching gate electrode 154 are connected to each other through a contact hole. The switching source electrode 173 is connected to the data line 171. The switching drain electrode 174 is spaced apart from the switching source electrode 173 and connected to one capacitor plate 158.

The driving thin film transistor 20 applies driving power for emitting light of the organic emission layer 720 of the OLED 130 in the selected pixel to the first electrode 710. The first driving gate electrode 154 is connected with the capacitor plate 158 which is connected with the switching drain electrode 174. Although not illustrated, the first driving gate electrode 154 and the second driving gate electrode 155 are connected to each other through a contact hole. The driving source electrode 176 and the other capacitor plate 178 are connected with the common power line 172, respectively. The driving drain electrode 177 is connected with the first electrode 710 of the OLED 130 through a contact hole.

The first gate electrodes 152 and 154 may be made of the same material as a first pad 156 to be described below, and the second gate electrodes 153 and 155 may be made of the same material as a second pad 157 to be described below. That is, the first gate electrodes 152 and 154 may be formed together by the same process as the first pad 156, and the second gate electrodes 153 and 155 may be formed together by the same process as the second pad 157 to be described below.

The switching source electrode 173, the switching drain electrode 174, the driving source electrode 176, and the driving drain electrode 177 are formed on the same layer and may be made of the same material as a third pad 179 to be described below. That is, the switching source electrode 173, the switching drain electrode 174, the driving source electrode 176, and the driving drain electrode 177 are formed together by the same process as the third pad 179 to be connected to each other.

By such a structure, the switching thin film transistor 10 serves to operate by the gate voltage applied to the gate line 151 to transfer a data voltage applied to the data line 171 to the driving thin film transistor 20. A voltage which corresponds to a difference between the common voltage applied to the driving thin film transistor 20 from the common power line 172 and the data voltage transferred from the switching thin film transistor 10 is stored in the capacitor 80, and a current which corresponds to the voltage stored in the capacitor 80 flows to the OLED 130 through the driving thin film transistor 20 to emit light by the OLED 130.

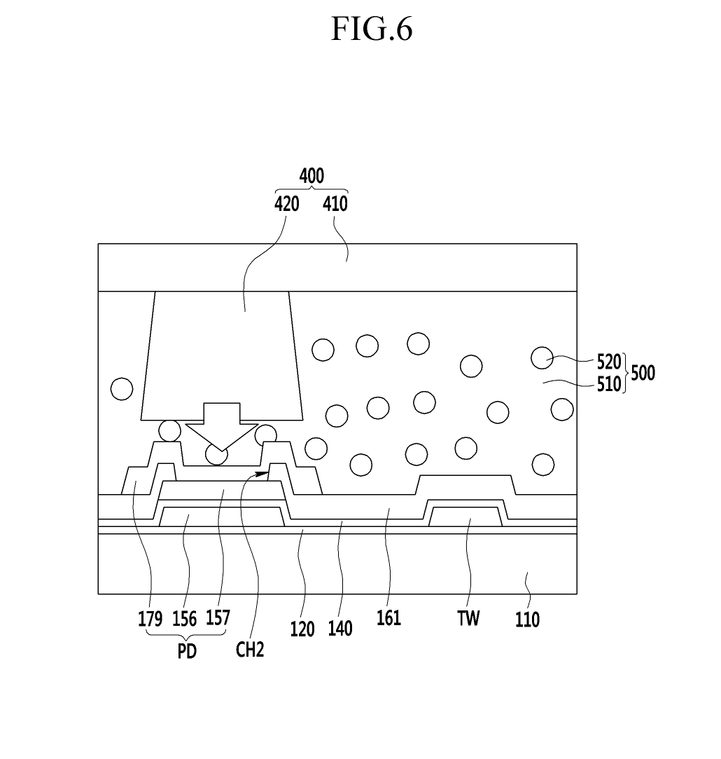

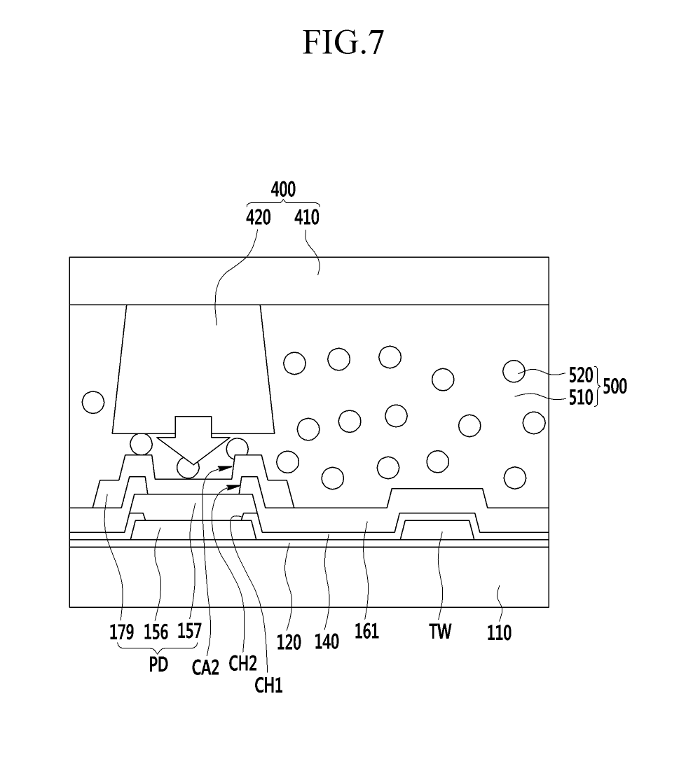

FIG. 5 is a plan view enlarging part V of FIG. 1, FIG. 6 is a cross-sectional view taken along line VI-VI of FIG. 5 as a cross-sectional view taken according to the exemplary embodiment, and FIG. 7 is a cross-sectional view taken along line VII-VII of FIG. 5 as a cross-sectional view according to the exemplary embodiment.

As illustrated in FIGS. 5 to 7, the pad part or pad portion PD includes a first pad 156, a second pad 157, and a third pad 179.

The first pad 156 is connected to a thin film wire Tw extending from the wire part 120. For example, the thin film wire Tw connects the gate line 151 and the first pad 156. The thin film wire Tw may be made of the same material as the gate line 151. That is, the first pad 156 may be made of the same material as the first gate electrodes 152 and 154 and the gate line 151 and formed together by the same process.

The second pad 157 may be formed on the first pad 156. A second gate insulating layer 140 is formed between the first pad 156 and the second pad 157.

The second gate insulating layer 140 is configured by a first region A1 in which a first contact hole CH1 is formed and a second region A2 in which the first contact hole CH1 is not formed. The first pad 156 and the second pad 157 are electrically connected to each other through the first contact hole CH1.

The second pad 157 may be made of the same material as the second gate electrodes 153 and 155 and formed together by the same process.

In this case, the second pad 157 may be formed at a predetermined height. For example, the second pad 157 may have a height of about 2,000 Å or greater.

The third pad 179 may be formed on the second pad 157. The passivation layer 161 including a second contact hole CH2 is formed between the second pad 157 and the third pad 179. The second pad 157 and the third pad 179 are connected to each other through the second contact hole CH2.

The third pad 179 may be made of the same material as the switching source electrode 173, the switching drain electrode 174, the driving source electrode 176, and the driving drain electrode 177 and formed together by the same process.

The third pad 179 is positioned to correspond to the integrated circuit chip 400 and connected with the integrated circuit chip 400 by the ACF 500.

Here, the fact that the third pad 179 is positioned to correspond to the integrated circuit chip 400 may mean that when the integrated circuit chip 400 is placed on the substrate 110 to be connected with the third pad 179, the third pad 179 is positioned to be covered by the integrated circuit chip 400.

The integrated circuit chip 400 may include a main body part 410 and a bump 420 positioned below the main body part 410.

The integrated circuit chip 400 and the pad part PD may be connected to each other by a chip on glass (COG) method by which the bump 420 is attached to the third pad 179.

The COG method is a method of attaching the integrated circuit chip 400 to the substrate 110 of the display device by only the bump 420 and the ACF 500 without using a film which is used by a tape automated bonding (TAP) method, in which the integrated circuit chip 400 is directly mounted on the substrate 110.

That is, when the ACF 500 including conductive balls 520 and an adhesive layer 510 is coated on the pad part PD and the bump 420 of the integrated circuit chip 400 is pressed thereon, the conductive balls 520 of the ACF 500 coated between the bump 420 and the third pad 179 of the pad part PD are pressed and thus the bump 420 and the third pad 179 of the pad part PD are electrically connected to each other.

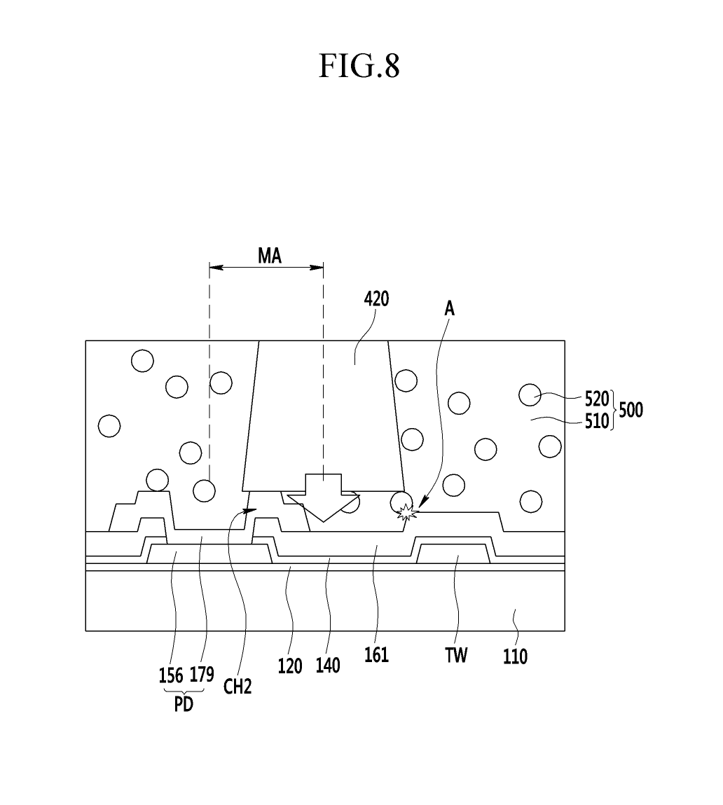

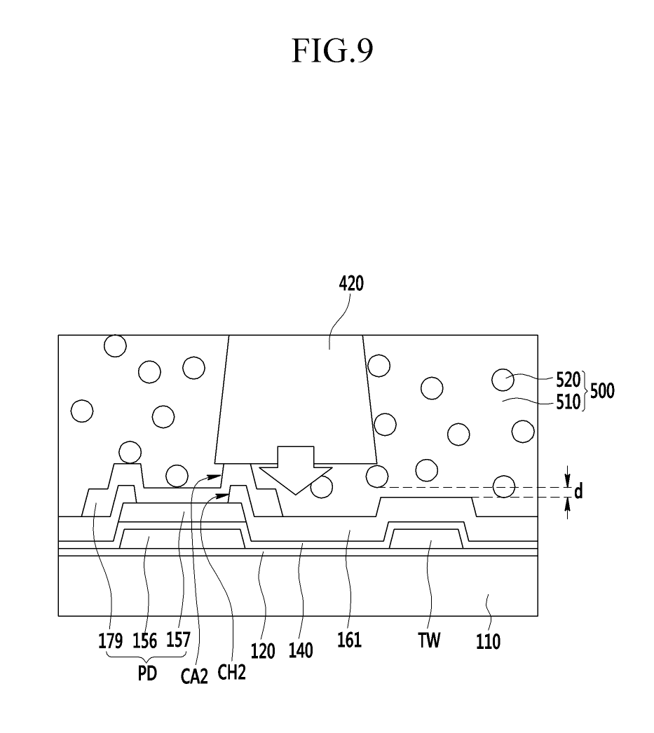

FIG. 8 is a cross-sectional view illustrating a display device according to a Comparative Example (not necessarily prior art) and is the same as the display device of FIG. 6 described above except that the structure of a pad part PD is changed. Accordingly, like constituent elements designate like reference numerals, and the duplicated description of like constituent elements will be omitted. FIG. 9 is a cross-sectional view illustrating the display device according to the exemplary embodiment.

As illustrated in FIG. 8, the display device according to the Comparative Example includes a pad part PD and a bump 420 of an integrated circuit chip.

The pad part PD includes a first pad 156 and a third pad 179. That is, in comparison with the pad part PD according to the exemplary embodiment, the pad part PD according to the Comparative Example does not include a second pad 157.

While the integrated circuit chip including the bump 420 and the pad part PD are connected to each other by the COG method, the bump 420 and the pad part PD may be misaligned, and as a result, the conductive balls 520 between the bump 420 and the pad part PD press the passivation layer 161 formed on the thin film wire Tw and thus a crack A may occur in the passivation layer 161.

That is, in the display device according to the Comparative Example, while the integrated circuit chip and the pad part PD are connected to each other, the passivation layer 161 may be broken by the conductive balls 520, and the thin film wire Tw formed below the passivation layer 161 is corroded.

On the other hand, as illustrated in FIG. 9, in the display device according to the exemplary embodiment, the pad part PD may include a first pad 156, a second pad 157, and a third pad 179.

The second pad 157 is further included between the first pad 156 and the third pad 179 to form a higher step of the pad part PD than that of the thin film wire Tw, and as a result, even in the case where the bump 420 and the pad part PD are misaligned (MA), the problem that the conductive balls 520 are bumped into the passivation layer 161 and thus the crack occurs may be improved.

While the inventive technology has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A display device, comprising:
a substrate;
a pad portion positioned over the substrate; and
an integrated circuit chip electrically connected to the pad portion and formed over the substrate,
wherein the pad portion includes a first pad positioned over the substrate, a second pad positioned over the first pad, and a third pad positioned over the second pad.

2. The display device of claim 1, further comprising a thin film transistor, wherein the thin film transistor includes first and second gate electrodes, and source and drain electrodes, wherein the first pad is formed of the same material as the first gate electrode, wherein the second pad is formed of the same material as the second gate electrode, and wherein the third pad is formed of the same material as the source and drain electrodes.

3. The display device of claim 1, further comprising a second gate insulating layer positioned between the first and second pads, and wherein the second gate insulating layer includes a first region in which a first contact hole is not formed and a second region in which the first contact hole is formed.

4. The display device of claim 3, wherein the first and second pads are electrically connected to each other through the first contact hole in the second region.

5. The display device of claim 1, further comprising a passivation layer positioned between the second and third pads, wherein the passivation layer includes a second contact hole connecting the second and third pads.

6. The display device of claim 5, wherein the second and third pads are electrically connected to each other through the second contact hole.

7. The display device of claim 1, wherein the integrated circuit chip includes a main body and a bump positioned below the main body.

8. The display device of claim 7, wherein the bump is attached to the third pad.

9. The display device of claim 8, further comprising an anisotropic conductive film containing a plurality of conductive balls coated on the third pad.

10. The display device of claim 9, wherein the bump of the integrated circuit chip is electrically connected to the third pad through the anisotropic conductive film.

11. The display device of claim 1, wherein the second pad has a height of about 2,000 Å or greater.

12. The display device of claim 1, further comprising:
a first electrode electrically connected to a drain electrode;
an organic emission layer positioned over the first electrode; and
a second electrode positioned over the organic emission layer.

13. The display device of claim 12, further comprising an encapsulation body connected to the substrate, wherein the pad portion is formed at a region of the substrate which is not covered by the encapsulation body.

14. A display device, comprising:
a substrate;
at least three pads positioned over the substrate; and
an integrated circuit chip electrically connected to the pads and formed over the substrate,
wherein the at least three pads comprise a first pad positioned over the substrate, a second pad positioned over the first pad, and a third pad positioned over the second pad.

15. The display device of claim 14, wherein the integrated circuit chip includes a main body and a bump positioned below the main body.

16. The display device of claim 16, wherein the bump is formed substantially directly above the pads.

17. The display device of claim 14, further comprising an anisotropic conductive film containing a plurality of conductive balls coated on the third pad.

18. The display device of claim 18, wherein at least some of the conductive balls are positioned between the third pad and the bump.

19. The display device of claim 14, wherein each of the first and second pads has a substantially linear shape, and wherein the third pad has a non-linear shape.

20. The display device of claim 14, wherein the second pad has a height of about 2,000 Å or greater.
